(19) United States
(12) Patent Application Publication
(10) Pub. No.: US 2013/0269991 A1
(43) Pub. Date: Oct. 17, 2013

(54) TOUCH PANEL

(71) Applicants: Youn Soo KIM, Gyunggi-do (KR); Jae Chan PARK, Gyunggi-do (KR); Young Jae KIM, Gyunggi-do (KR); Tae Hoon KIM, Gyunggi-do (KR)

(72) Inventors: Youn Soo KIM, Gyunggi-do (KR); Jae Chan PARK, Gyunggi-do (KR); Young Jae KIM, Gyunggi-do (KR); Tae Hoon KIM, Gyunggi-do (KR)

(73) Assignee: SAMSUNG ELECTRO-MECHANICS CO., LTD., Gyunggi-do (KR)

(21) Appl. No.: 13/549,174

(22) Filed: Jul. 13, 2012

(30) Foreign Application Priority Data
Apr. 17, 2012 (KR) 10-2012-0039841

(51) Int. Cl. H05K 1/00; H05K 1/09

(52) U.S. Cl. 174/257; 174/250

(57) ABSTRACT

Disclosed herein is a touch panel. A touch panel 100 according to a preferred embodiment of the present invention is configured to include a first transparent substrate 110, electrode patterns 120 formed on the first transparent substrate 110, a second transparent substrate 130 disposed more outwardly than the first transparent substrate 110, and micro lenses 140 formed on the second transparent substrate 130 to correspond to the electrode patterns 120 so as to focus an erected virtual image I of the electrode patterns 120 having magnification of 1 or less thereon. By this configuration, a user 150 recognizes the erected virtual images I of the electrode pattern 120 with the reduced magnification of 1 or less through the micro lenses 140, thereby improving the visibility of the touch panel 100.

### CROSS REFERENCE TO RELATED APPLICATION

This application claims the benefit of Korean Patent Application No. 10-2012-0039841, filed on Apr. 17, 2012, entitled “Touch Panel”, which is hereby incorporated by reference in its entirety into this application.

### BACKGROUND OF THE INVENTION

1. Technical Field

The present invention relates to a touch panel.

2. Description of the Related Art

In accordance with the growth of computers using a digital technology, devices assisting computers have also been developed, and personal computers, portable transmitters and other personal information processors execute processing of text and graphics using a variety of input devices such as a keyboard and a mouse.

While the rapid advancement of an information-oriented society has widened the use of computers more and more, it is difficult to efficiently operate products using only a keyboard and a mouse currently serving as an input device. Therefore, the necessity for a device that is simple, has minimum malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of an image display device such as an electronic organizer, a flat panel display device including a liquid crystal display (LCD) device, a plasma display panel (PDP), an electroluminescence (El) element, or the like, and a cathode ray tube (CRT) to thereby be used to allow users to select desired information while viewing the image display device.

In addition, the touch panel is classified into a resistive type touch panel, a capacitive type touch panel, an electromagnetic type touch panel, a surface acoustic wave (SAW) type touch panel, and an infrared type touch panel. These various types of touch panels are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields.

Meanwhile, as described in Patent Document of the following Prior Art Document with reference to the touch panel, researches for forming electrodes in a mesh pattern using metals have been actively progressed. As described above, when the electrodes are formed in the mesh pattern, there is an advantage in that the touch panel has excellent electric conductivity and a demand and supply thereof is smooth. However, when the electrode patterns are formed of opaque metals, the electrode patterns may be recognized by users and therefore, visibility of the touch panel may be degraded.

In order to solve the above problems, a method for reducing a line width of the mesh pattern as maximally as possible. In this case, the mesh pattern has degraded durability and conductivity, limited manufacturing methods, and increased manufacturing costs.

Further, a method for preventing reflection of light by performing a black oxide treatment on the mesh pattern can be considered. In this case, the method oxidizes a surface of the mesh pattern to form metal oxide, thereby degrading electrical characteristics.

### PRIOR ART DOCUMENT

### Patent Document

(Patent Document 1) US 2010-0123670 A1

### SUMMARY OF THE INVENTION

The present invention has been made in an effort to provide a touch panel capable of reducing line widths of an electrode patterns recognized by users by adopting micro lenses.

According to a first preferred embodiment of the present invention, there is provided a touch panel, including: a first transparent substrate; electrode patterns formed on the first transparent substrate; and micro lenses formed to correspond to the electrode patterns so as to focus erected virtual images of the electrode patterns having magnification of 1 or less thereon.

A width of the micro lens may be equal to a line width of the electrode pattern.

A width of the micro lens may be larger than a line width of the electrode pattern.

A longitudinal central axis of the micro lens may correspond to a longitudinal central axis of the electrode pattern.

The micro lens may be formed of acrylic polymer.

The electrode patterns may be formed in a mesh pattern.

The electrode pattern may be formed of copper (Cu), aluminum (Al), gold (Au), silver (Ag), titanium (Ti), palladium (Pd), and chromium (Cr), or a combination thereof.

The electrode pattern may be formed of metal silver formed by exposing/developing a silver halide emulsion layer.

The micro lenses may be formed on the second transparent substrate and the second transparent substrate may be disposed more outwardly than the first transparent substrate.

The micro lenses may be formed by patterning the second transparent substrate.

According to a second preferred embodiment of the present invention, there is provided a touch panel, including: a transparent substrate; electrode patterns formed on one surface of the transparent substrate; and micro lenses formed on the other surface of the transparent substrate to correspond to the electrode patterns so as to focus erected virtual images of the electrode patterns having magnification of 1 or less thereon.

A width of the micro lens may be equal to a line width of the electrode pattern.

A width of the micro lens may be larger than a line width of the electrode pattern.

A longitudinal central axis of the micro lens may correspond to a longitudinal central axis of the electrode pattern.

The micro lens may be formed of acrylic polymer.

The micro lenses may be formed by patterning the transparent substrate.

The electrode patterns may be formed in a mesh pattern.

The electrode pattern may be formed of copper (Cu), aluminum (Al), gold (Au), silver (Ag), titanium (Ti), palladium (Pd), and chromium (Cr), or a combination thereof.

The electrode pattern may be formed of metal silver formed by exposing/developing a silver halide emulsion layer.

### BRIEF DESCRIPTION OF THE DRAWINGS

The above and other objects, features and advantages of the present invention will be more clearly understood from the following detailed description taken in conjunction with the accompanying drawings, in which:

FIGS. 1A and 1B are a plan view and a cross-sectional view of a touch panel according to a first preferred embodiment of the present invention;

FIGS. 2A and 2B are enlarged concept diagrams of the electrode patterns and the micro lenses shown in FIG. 1B;

FIGS. 3 to 6 are cross-sectional views of a touch panel having a modified shape according to the first preferred embodiment of the present invention;

FIGS. 7A and 7B are a plan view and a cross-sectional view of a touch panel according to a second preferred embodiment of the present invention;

FIGS. 8A and 8B are enlarged concept diagrams of the electrode patterns and the micro lenses shown in FIG. 7B; and

FIGS. 9 to 11 are cross-sectional views of a touch panel having a modified shape according to the second preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

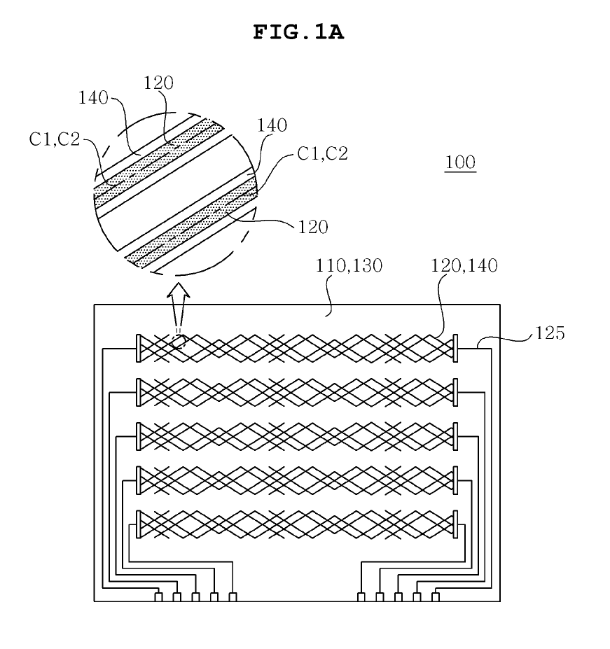

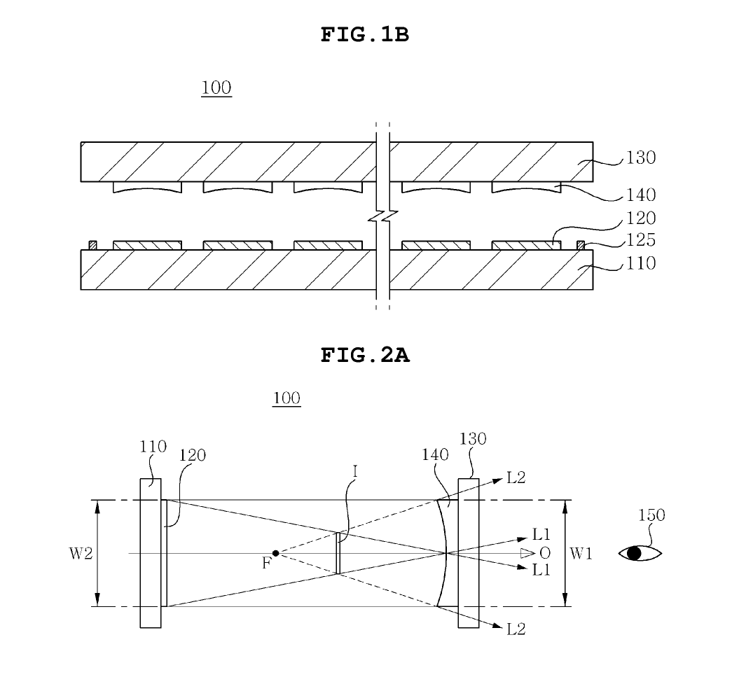

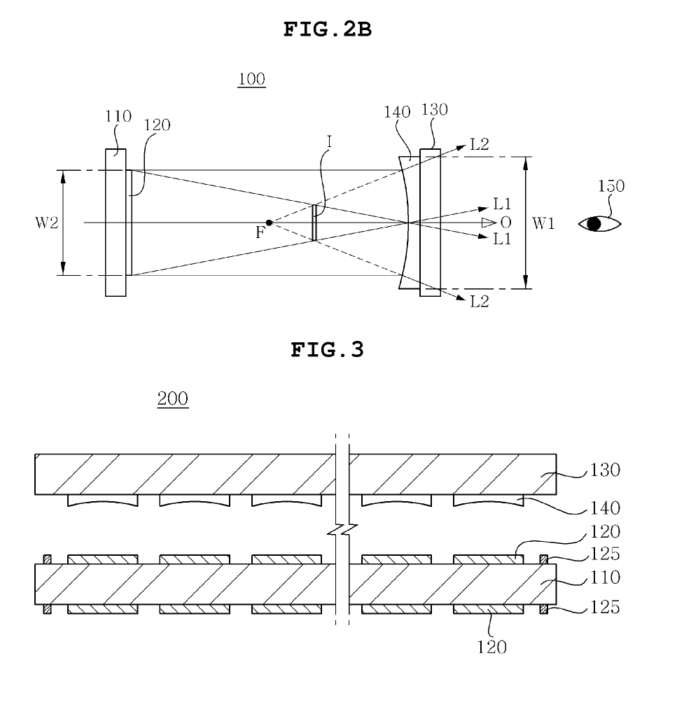

FIGS. 1A and 1B are a plan view and a cross-sectional view of a touch panel according to a first preferred embodiment of the present invention and FIGS. 2A and 2B are an enlarged concept diagram of electrode pattern and micro lenses shown in FIG. 1B.

As shown in FIGS. 1 and 2, a touch panel 100 according to the first preferred embodiment of the present invention is configured to include a first transparent substrate 110, electrode patterns 120 formed on the first transparent substrate 110, a second transparent substrate 130 disposed more outwardly than the first transparent substrate 110, and micro lenses 140 formed on the second transparent substrate 130 to correspond to the electrode patterns 120 so as to focus erected virtual images I of the electrode patterns 120 having magnification of 1 or less thereon.

The first and second transparent substrates 110 and 130 serve to provide an area in which the electrode patterns 120, the micro lenses, and the like, are formed. In detail, the electrode patterns 120 are formed on the first transparent substrate 110 and the micro lenses 140 are formed on the second transparent substrate 130. In this configuration, the micro lenses 140 serve to reduce a phenomenon that the electrode patterns are recognized by users. Therefore, the second transparent substrate 130 on which the micro lenses 140 are formed is disposed more outwardly than the first transparent substrate 110 on which the electrode patterns 120 are formed. In addition, the first and second transparent substrates 110 and 130 need to have support force that can support the electrode patterns 120, the micro lens 140, and the like, and transparency that can allow users to recognize images provided from an image display device. In consideration of the support force and the transparency described above, the first and second transparent substrates 110 and 130 may be made of polyethylene terephthalate (PET), polycarbonate (PC), poly methyl methacrylate (PMMA), polyethylene naphthalate (PEN), polyethersulpon (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), glass, or tempered glass, but are not necessarily limited thereto.

The electrode patterns 120 serve to allow a controller to recognize touched coordinates by detecting a change in capacitance when being touched and are formed on the first transparent substrate 110. Here, the electrode patterns 120 may be formed in a bar type pattern as shown in FIG. 1A, but is not limited thereto. Therefore, the electrode pattern 120 may be formed in all the patterns known to those skilled in the art such as a diamond pattern, a quadrangular pattern, a triangular pattern, a circular pattern, and the like. In addition, the electrode patterns 120 may be formed of copper (Cu), aluminum (Al), gold (Au), silver (Ag), titanium (Ti), palladium (Pd), and chromium (Cr), or a combination thereof. In detail, the electrode patterns 120 may be preferably formed of copper (Cu), aluminum (Al), gold (Au), silver (Ag), and the like, all of which have high electric conductivity, but may be formed of all metals having electric conductivity. In addition to the foregoing metals, the electrode patterns may be formed of metal silver formed by exposing/developing a silver halide emulsion layer. Meanwhile, when the electrode patterns 120 are formed of opaque metals as described above, the electrode patterns 120 may be formed in a mesh pattern having a fine line width so that the electrode patterns 120 are not recognized by the users as maximally as possible. However, durability and conductivity may be degraded due to the excessive reduction in line widths of the electrode patterns 120 and therefore, there is a limitation in reducing the line widths of the electrode patterns 120 and the electrode patterns 120 need to have a line width above a predetermined width. Therefore, the touch panel 100 according to the preferred embodiment of the present invention prevents the electrode patterns 120 from being recognized by the users by adopting the micro lenses 140 rather than by excessively reducing the line widths of the electrode patterns 120 and a detailed description thereof will be described below.

Meanwhile, electrode wirings 125 (see FIG. 1A) receiving electrical signals from the electrode patterns 120 may be formed at edges of the electrode patterns 120. Here, the electrode wirings 125 may be formed of copper (Cu), aluminum (Al), gold (Au), silver (Ag), titanium (Ti), palladium (Pd), and chromium (Cr) or a combination thereof, similarly to the electrode patterns 120, but are not limited thereto. Therefore, the electrode patterns 125 may be formed of the metal silver formed by exposing/developing the silver halide emulsion layer. Meanwhile, the electrode wirings 125 may be integrally formed with the electrode patterns 120, if necessary. As such, it is possible to previously prevent a bonding defect between the electrode wirings 125 and the electrode patterns 120 by integrally forming the electrode wirings 125 and the electrode patterns 120, simplify a manufacturing process, and shorten lead time.

The micro lenses 140 serve to reduce the phenomenon that the electrode patterns 120 are recognized by the users and are formed on the second transparent substrate 130. Here, the micro lenses 140 are formed to correspond to the electrode patterns 120 so as to focus erected virtual images I of the electrode patterns 120 having magnification of 1 or less thereon as shown in FIG. 2. In detail, light L1 transmitting centers of the micro lenses 140 passes through as it is and light L2 transmitting the micro lenses 140 so as to parallel with an optical axis O is emitted like light from a virtual focus F. In this case, the erected virtual images I are focused on a point at which the light L1 transmitting the centers of the micro lenses 140 meets an extension line of the light L2 transmitting the micro lens 140 so as to parallel with the optical axis O and therefore, has the magnification of 1 or less, such that a user 150 is recognized smaller than the real electrode patterns 120. As such, the user 150 recognizes the erected virtual images I of the electrode pattern 120 with the reduced magnification of 1 or less through the micro lenses 140, thereby improving the visibility of the touch panel 100. In addition, a line width W2 of the electrode pattern 120 recognized by the user 150 can be controlled as desired by controlling a refractive index of the micro lenses 140, as needed. Meanwhile, a width W1 of the micro lens 140 may be equal to (see FIG. 2A) or larger than (see FIG. 2B) the line width W2 of the electrode pattern 120 so that the micro lenses 140 may focus the erected virtual images I on all the portions of the electrode patterns 120. In addition, a longitudinal central axis C1 of the micro lens 140 may correspond to a longitudinal central axis C2 of the electrode pattern 120 so that the micro lens 140 accurately correspond to the electrode pattern 120 (see the enlarged view of FIG. 1A). Meanwhile, the micro lens 140 may be formed of acrylic polymer. In this case, the micro lens 140 may be formed by applying the acrylic polymer by spin coating, and the like, and then, stamping it. In addition, the micro lens 140 may be integrally with the second transparent substrate 130 by patterning the second transparent substrate 130 itself. Meanwhile, although FIG. 1B shows that the micro lenses 140 are formed on an inner side of the second transparent substrate 130 so as to face the electrode patterns 120, the micro lenses 140 may be formed on an outer side of the second transparent substrate 130.

The touch panel 100 according to the preferred embodiment of the present invention is described with reference to a capacitive type touch panel in which the electrode patterns 120 are formed on one surface of the first transparent substrate 110, but this is illustrated by way of example only. Therefore, the touch panel according to the preferred embodiment of the present invention may be modified as described below.

FIGS. 3 to 6 are cross-sectional views of a touch panel having a modified shape according to the first preferred embodiment of the present invention.

As shown in FIG. 3, a capacitive type touch panel 200 (see FIG. 3) can be manufactured by forming the electrode patterns 120 on both surfaces of the first transparent substrate 110, respectively.

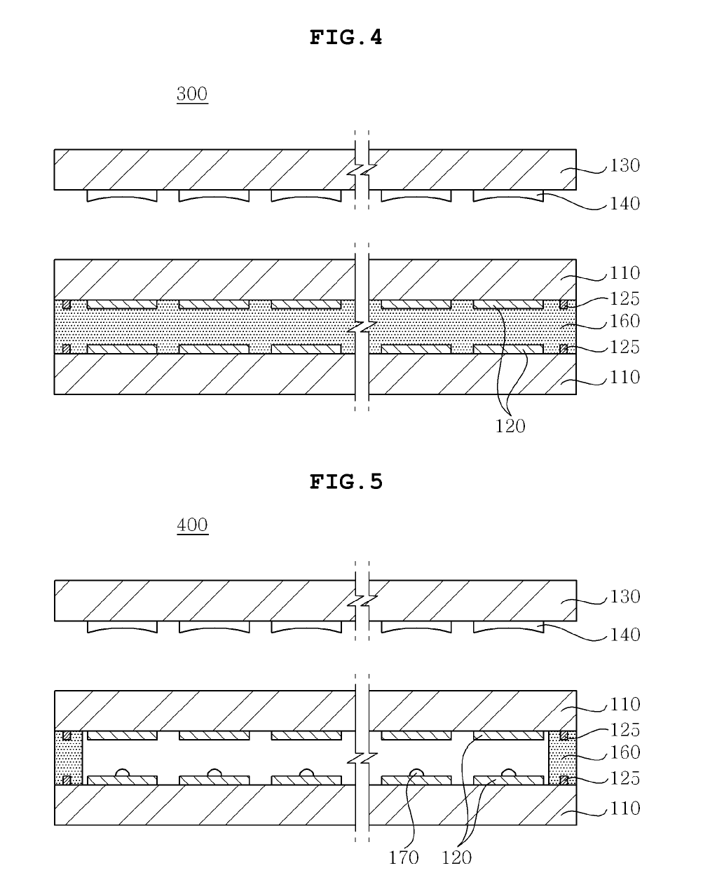

Further, FIGS. 4 to 5 show that a capacitive type touch panel 300 (see FIG. 4) or a resistive type touch panel 400 (see FIG. 5) formed by providing two first transparent substrate 110 having the electrode patterns 120 formed on one surface thereof and bonding the two first transparent substrates 110 to each other by an adhesive layer 160 so as to face the electrode patterns 120 each other. Here, in the case of the capacitive type touch panel 300 (see FIG. 4), the adhesive layer 160 is attached to a front surface of the first transparent substrate 110 so as to insulate the two facing electrode patterns 120 from each other. On the other hand, in the case of the resistive type touch panel 400 (see FIG. 5), when pressure of an input unit is applied, the adhesive layer 160 is attached only to the edges of the first transparent substrate 110 so as to bond the two facing electrode patterns 120 to each other and when the pressure of the input unit is removed, dot spacers 170 providing repulsive force to return the electrode patterns to an original position are provided on exposed surfaces of the electrode patterns 120.

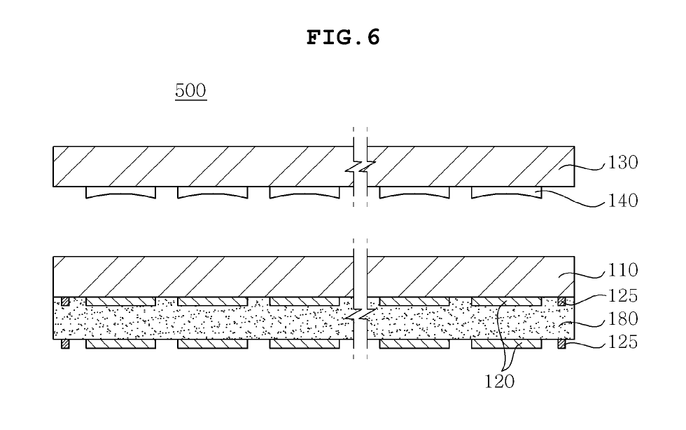

Meanwhile, as shown in FIG. 6, a capacitive type touch panel 500 (see FIG. 6) may be manufactured by forming the electrode patterns 120 on the first transparent substrate 110, forming an insulating layer 180 thereon, and again forming the electrode patterns thereon. Here, the insulating layer 180 may be formed of epoxy, acrylic-based resin, an SiOx thin film, an SiNx thin film, and the like.

The touch panels 200, 300, 400, and 500 having a modified shape according to the first preferred embodiment of the present invention also allow the users to recognize the erected virtual image of the electrode patterns 120 with the reduced magnification of 1 or less through the micro lenses 140, thereby improving the visibility of the touch panels 200, 300, 400, and 500.

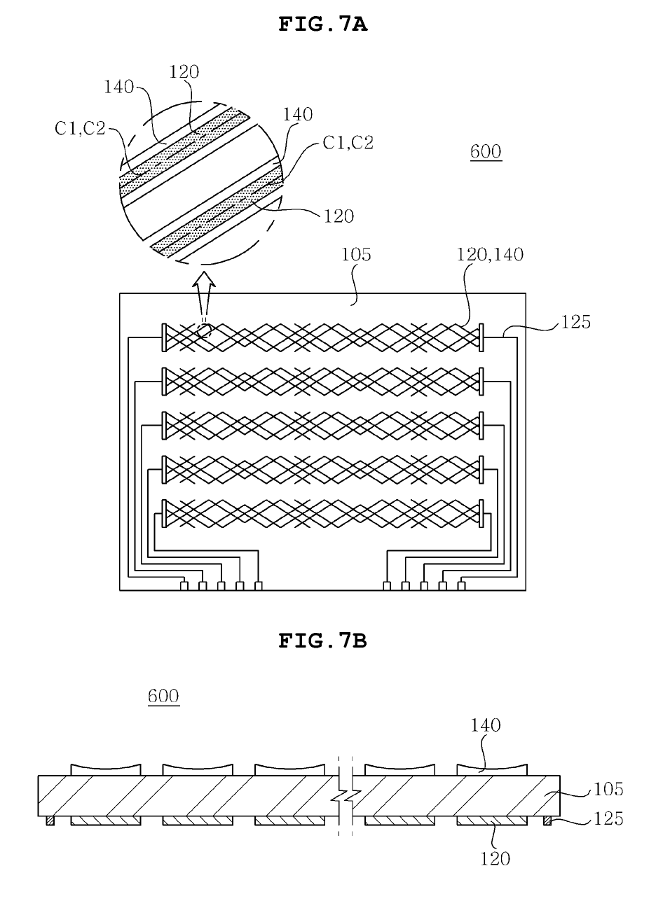

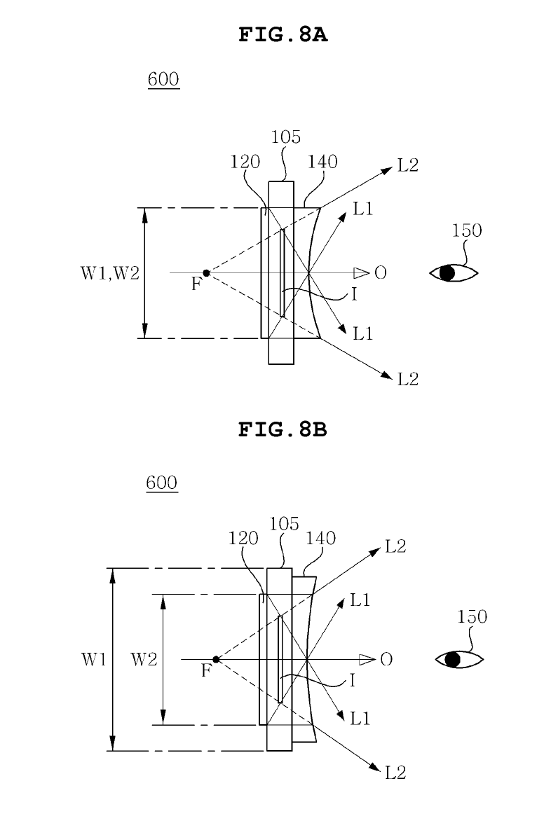

FIGS. 7A and 7B are a plan view and a cross-sectional view of a touch panel according to a second preferred embodiment of the present invention and FIGS. 8A and 8B are an enlarged concept diagram of an electrode pattern and a micro lens shown in FIG. 7B.

As shown in FIGS. 7 and 8, a touch panel 600 according to a second preferred embodiment of the present invention is configured to include a transparent substrate 105, the electrode patterns 120 formed on one surface of the transparent substrate 105, and the micro lenses 140 formed on the other surface of the transparent substrate 105 to correspond to the electrode patterns 120 so as to focus the erected virtual images I of the electrode patterns 120 having the magnification of 1 or less thereon.

When the touch panel 600 according to the second preferred embodiment of the present invention compares with the touch panel 100 according to the first preferred embodiment of the present invention, the first preferred embodiment of the present invention is different from the second preferred embodiment of the present invention in that the electrode patterns 120 and the micro lenses 140 are formed at different positions. Therefore, the touch panel 600 according to the second preferred embodiment of the present invention is described based on the foregoing difference and the contents overlapping with the touch panel 100 according to the first preferred embodiment of the present invention will be omitted.

The transparent substrate 105 serves to provide an area in which the electrode patterns 120, the micro lenses 140, and the like, are formed. In detail, the electrode patterns 120 are formed on one surface of the transparent substrate 105 and the micro lenses 140 are formed on the other surface of the transparent substrate 105. In this configuration, the micro lenses 140 serve to reduce a phenomenon that the electrode patterns are recognized by a user. Therefore, the other surface of the transparent substrate 105 on which the micro lenses 140 are formed is disposed more outwardly than one surface of the transparent substrate 105 on which the electrode patterns 120 are formed.

The electrode patterns 120 serve to allow a controller to recognize touched coordinates by detecting a change in capacitance when being touched and are formed on one surface of the transparent substrate 105. Here, the electrode patterns 120 may be formed of copper (Cu), aluminum (Al), gold (Au), silver (Ag), titanium (Ti), palladium (Pd), and chromium (Cr), or a combination thereof or may be formed of the metal silver formed by exposing/developing the silver halide emulsion layer. Meanwhile, when the electrode patterns 120 are formed of opaque metals as described above, the electrode patterns 120 may be formed in a mesh pattern having a fine line width so that the electrode patterns 120 are not recognized by the user as maximally as possible. In addition, the electrode wirings 125 (see FIG. 7A) receiving the electrical signals from the electrode patterns 120 may be formed at the edges of the electrode patterns 120.

The micro lenses 140 serve to reduce the phenomenon that the electrode patterns 120 are recognized by the users and are formed on the other surface (a surface opposite to the one surface on which the electrode patterns 120 are formed) of the transparent substrate 105. Here, the micro lenses 140 are formed to correspond to the electrode patterns 120 so as to focus erected virtual images I of the electrode patterns 120 having magnification of 1 or less thereon as shown in FIG. 8. In detail, light L1 transmitting centers of the micro lenses 140 passes through as it is and light L2 transmitting the micro lenses 140 so as to parallel with an optical axis O is emitted like light from a virtual focus F. In this case, the erected virtual images I are focused on a point at which the light L1 transmitting the centers of the micro lenses 140 meets an extension line of the light L2 transmitting the micro lens 140 so as to parallel with the optical axis O and therefore, has the magnification of 1 or less, such that the user 150 is recognized smaller than the real electrode patterns 120. As such, the user 150 recognizes the erected virtual images I of the electrode pattern 120 with the reduced magnification of 1 or less through the micro lenses 140, thereby improving the visibility of the touch panel 600. Meanwhile, the width W1 of the micro lens 140 may be equal to (see FIG. 8A) or larger than (see FIG. 8B) the line width W2 of the electrode pattern 120 so that the micro lenses 140 may focus the erected virtual images I on all the portions of the electrode patterns 120. In addition, a longitudinal central axis C1 of the micro lens 140 may correspond to a longitudinal central axis C2 of the electrode pattern 120 so that the micro lens 140 accurately correspond to the electrode pattern 120 (see the enlarged view of FIG. 7A).

The touch panel 600 according to the preferred embodiment of the present invention is described with reference to a capacitive type touch panel in which the electrode patterns 120 are formed on one surface of the transparent substrate 105, but this is illustrated by way of example only. Therefore, the touch panel according to the preferred embodiment of the present invention may be modified as described below.

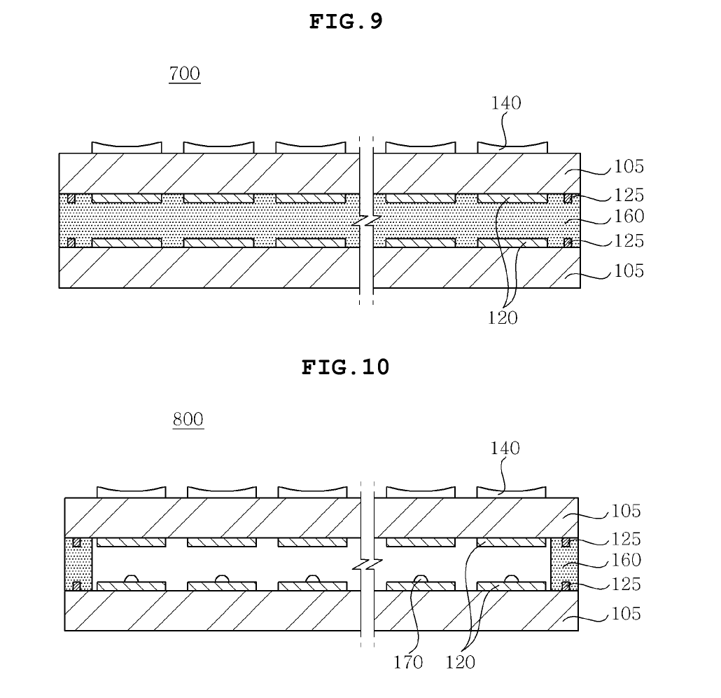

FIGS. 9 to 11 are cross-sectional views of a touch panel having a modified shape according to the second preferred embodiment of the present invention.

FIGS. 9 and 10 show that a capacitive type touch panel 700 (see FIG. 9) or a resistive type touch panel 800 (see FIG. 10) formed by further providing a separate transparent substrate 105 having the electrode patterns 120 formed on one surface thereof and bonding the two transparent substrates 105 to each other by the adhesive layer 160 so as to face the two electrode patterns 120 each other. Here, in the case of the capacitive type touch panel 700 (see FIG. 9), the adhesive layer 160 is attached to a front surface of the transparent substrate 105 so as to insulate the two facing electrode patterns 120 from each other. On the other hand, in the case of the resistive type touch panel 800 (see FIG. 10), when the pressure of the input unit is applied, the adhesive layer 160 is attached only to the edges of the transparent substrate 105 so as to bond the two facing electrode patterns 120 to each other and when the pressure of the input unit is removed, the dot spacers 170 providing the repulsive force to return the electrode patterns to an original position are provided on exposed surfaces of the electrode patterns 120.

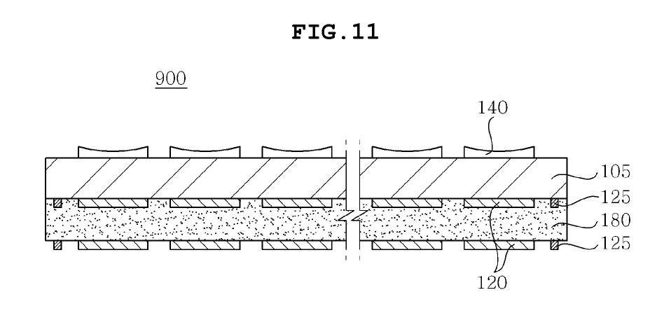

Meanwhile, as shown in FIG. 11, a capacitive type touch panel 900 (see FIG. 11) may be manufactured by forming the electrode patterns 120 on the transparent substrate 105, forming the insulating layer 180 thereon, and again forming the electrode patterns thereon.

The touch panels 700, 800, and 900 having a modified shape according to the second preferred embodiment of the present invention also allow the users to recognize the erected virtual image of the electrode patterns 120 with the reduced magnification of 1 or less through the micro lenses 140, thereby improving the visibility of the touch panels 700, 800, and 900.

According to the preferred embodiments of the present invention, the phenomenon that the electrode patterns are recognized by the users can be reduced by adopting the micro lenses and the visibility of the touch panel can be improved accordingly.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims

What is claimed is:

1. A touch panel, comprising:
a first transparent substrate;
electrode patterns formed on the first transparent substrate; and
micro lenses formed to correspond to the electrode patterns so as to focus erected virtual images of the electrode patterns having magnification of 1 or less thereon.

2. The touch panel as set forth in claim 1, wherein a width of the micro lens is equal to a line width of the electrode pattern.

3. The touch panel as set forth in claim 1, wherein a width of the micro lens is larger than a line width of the electrode pattern.

4. The touch panel as set forth in claim 1, wherein a longitudinal central axis of the micro lens corresponds to a longitudinal central axis of the electrode pattern.

5. The touch panel as set forth in claim 1, wherein the micro lens is formed of acrylic polymer.

6. The touch panel as set forth in claim 1, wherein the electrode patterns are formed in a mesh pattern.

7. The touch panel as set forth in claim 1, wherein the electrode pattern is formed of copper (Cu), aluminum (Al), gold (Au), silver (Ag), titanium (Ti), palladium (Pd), and chromium (Cr), or a combination thereof.

8. The touch panel as set forth in claim 1, wherein the electrode pattern is formed of metal silver formed by exposing/developing a silver halide emulsion layer.

9. The touch panel as set forth in claim 1, wherein the micro lenses are formed on the second transparent substrate, and the second transparent substrate is disposed more outwardly than the first transparent substrate.

10. The touch panel as set forth in claim 9, wherein the micro lenses are formed by patterning the second transparent substrate.

11. A touch panel, comprising:
a transparent substrate;
electrode patterns formed on one surface of the transparent substrate; and
micro lenses formed on the other surface of the transparent substrate to correspond to the electrode patterns so as to focus erected virtual images of the electrode patterns having magnification of 1 or less thereon.

12. The touch panel as set forth in claim 11, wherein a width of the micro lens is equal to a line width of the electrode pattern.

13. The touch panel as set forth in claim 11, wherein a width of the micro lens is larger than a line width of the electrode pattern.

14. The touch panel as set forth in claim 11, wherein a longitudinal central axis of the micro lens corresponds to a longitudinal central axis of the electrode pattern.

15. The touch panel as set forth in claim 11, wherein the micro lens is formed of acrylic polymer.

16. The touch panel as set forth in claim 11, wherein the micro lenses are formed by patterning the transparent substrate.

17. The touch panel as set forth in claim 11, wherein the electrode patterns are formed in a mesh pattern.

18. The touch panel as set forth in claim 11, wherein the electrode pattern is formed of copper (Cu), aluminum (Al), gold (Au), silver (Ag), titanium (Ti), palladium (Pd), and chromium (Cr), or a combination thereof.

19. The touch panel as set forth in claim 11, wherein the electrode pattern is formed of metal silver formed by exposing/developing a silver halide emulsion layer.
